(19) United States
(12) Patent Application Publication
(10) Pub. No.: US 2026/0092877 A1
(43) Pub. Date: Apr. 2, 2026

(54) INSPECTION APPARATUS AND METHOD FOR OPERATING THE SAME

(71) Applicant: TAIWAN SEMICONDUCTOR MANUFACTURING COMPANY, LTD., Hsinchu (TW)

(72) Inventors: Ping-Hung CHEN, Hsinchu County (TW); Hung-Tai TSAO, Hsinchu County (TW); Jun-Da LIN, Taipei City (TW); Ji-Jie CHOU, Hsinchu City (TW)

(73) Assignee: TAIWAN SEMICONDUCTOR MANUFACTURING COMPANY, LTD., Hsinchu (TW)

(21) Appl. No.: 18/901,512

(22) Filed: Sep. 30, 2024

(51) Int. Cl. G01N 21/95; H01L 21/67

(52) U.S. Cl. CPC G01N 21/9501; H10P 72/0616

(57) ABSTRACT

A method for operating an inspection apparatus is provided. The method includes placing a reticle over a stage; moving the stage by moving a vehicle supporting the stage on a rail; inspecting the reticle over the stage; and using a cleaning mechanism, generating a suction force nearby the rail.

### BACKGROUND

Generally, the semiconductor manufacturing industry involves highly complex techniques for fabricating integrating circuits using semiconductor materials, which are layered and patterned onto a substrate, such as silicon. An integrated circuit is fabricated from reticles. Initially, circuit designers provide circuit pattern data, which describes a particular integrated circuit (IC) design, to a reticle production system, which transforms the pattern data into reticles. Due to the large scale of circuit integration and the decreasing size of semiconductor devices, the reticles and fabricated devices have become increasingly sensitive to defects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic views of an inspection apparatus according to some embodiments of the present disclosure.

FIG. 1C is a top view of the inspection apparatus of FIGS. 1A and 1B.

FIG. 1D is a schematic view of a portion of an inspection apparatus of FIG. 1C.

FIG. 1E is a side schematic view of FIG. 1D.

FIG. 1F is a schematic view of a gas distributing structure and a cleaning mechanism of FIG. 1D.

FIG. 2A is a flow chart of a method for operating an inspection apparatus according to some embodiments of the present disclosure.

FIG. 2B shows pulses versus time for operating an inspection apparatus according to some embodiments of the present disclosure.

FIG. 2C shows a top view of the inspection apparatus under the operation of FIG. 2B.

FIG. 3A is a side schematic view of a portion of an inspection apparatus according to some embodiments of the present disclosure.

FIG. 3B is a schematic view of a gas distributing structure and a cleaning mechanism according to some embodiments of the present disclosure.

FIG. 4A is a side schematic view of a portion of an inspection apparatus according to some embodiments of the present disclosure.

FIG. 4B is a schematic view of a gas distributing structure and a cleaning mechanism according to some embodiments of the present disclosure.

FIG. 5 is a schematic view of a gas distributing structure and a cleaning mechanism according to some embodiments of the present disclosure.

FIG. 6 is a schematic view of a gas distributing structure and a cleaning mechanism according to some embodiments of the present disclosure.

FIG. 7 is a schematic view of a gas distributing structure and a cleaning mechanism according to some embodiments of the present disclosure.

FIG. 8 is a schematic view of a gas distributing structure and a cleaning mechanism according to some embodiments of the present disclosure.

FIG. 9 is a schematic view of a gas distributing structure and a cleaning mechanism according to some embodiments of the present disclosure.

FIG. 10 is a side schematic view of a portion of an inspection apparatus according to some embodiments of the present disclosure.

FIG. 11 is a side schematic view of a portion of an inspection apparatus according to some embodiments of the present disclosure.

FIG. 12 is a top view of a portion of an inspection apparatus according to some embodiments of the present disclosure.

FIG. 13 is a schematic view of a portion of an inspection apparatus according to some embodiments of the present disclosure.

FIG. 14 is a diagram illustrating a relationship between a vacuum force of a gas suction system and a particle concentration according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

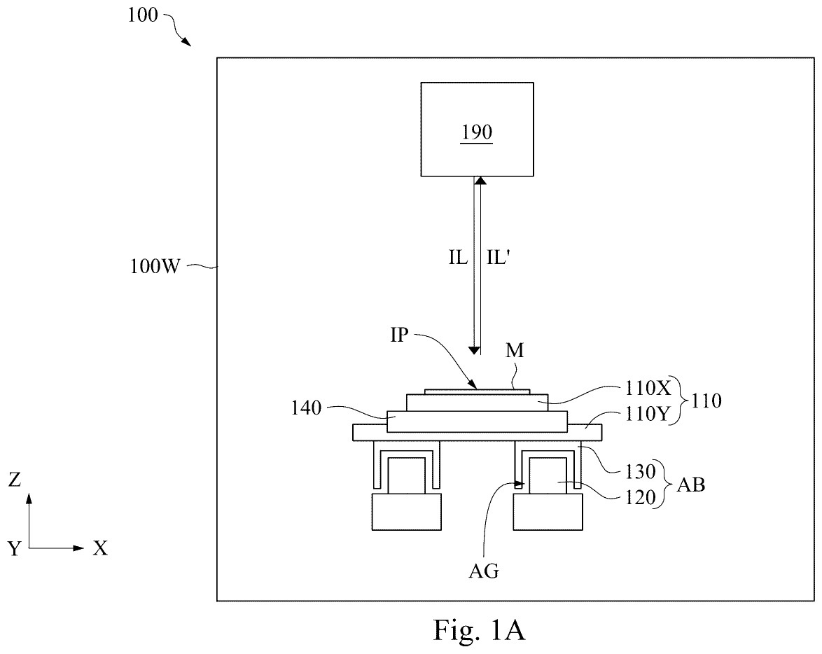

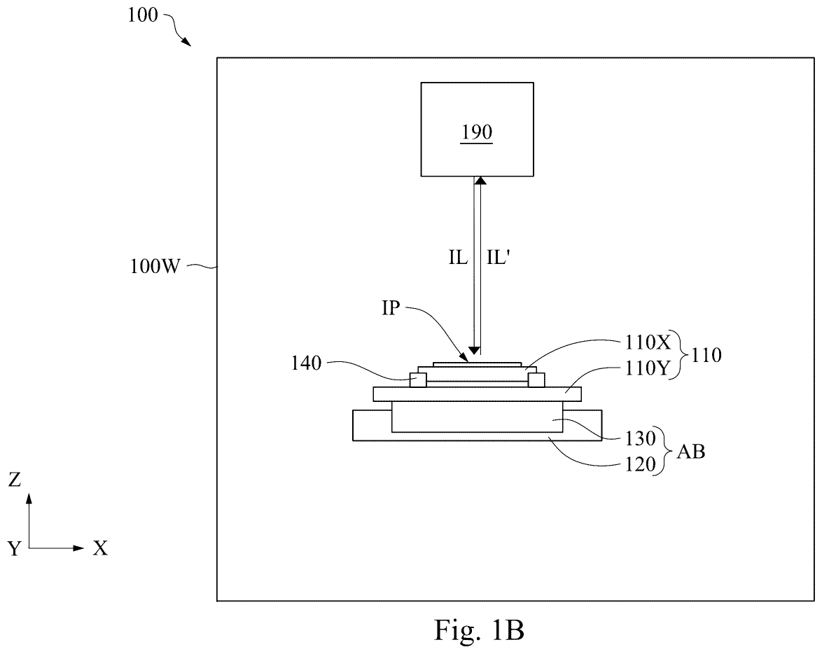

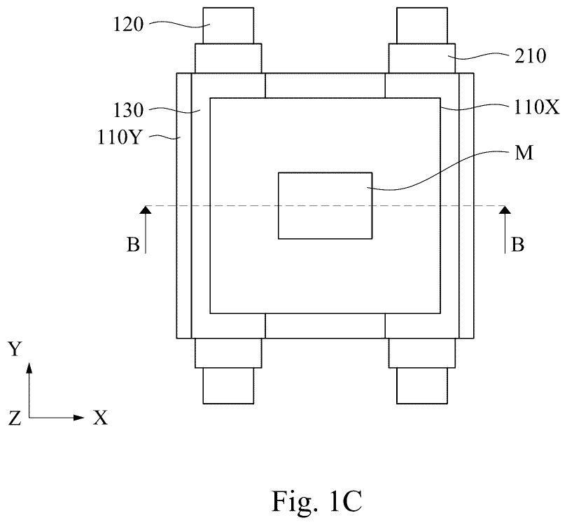

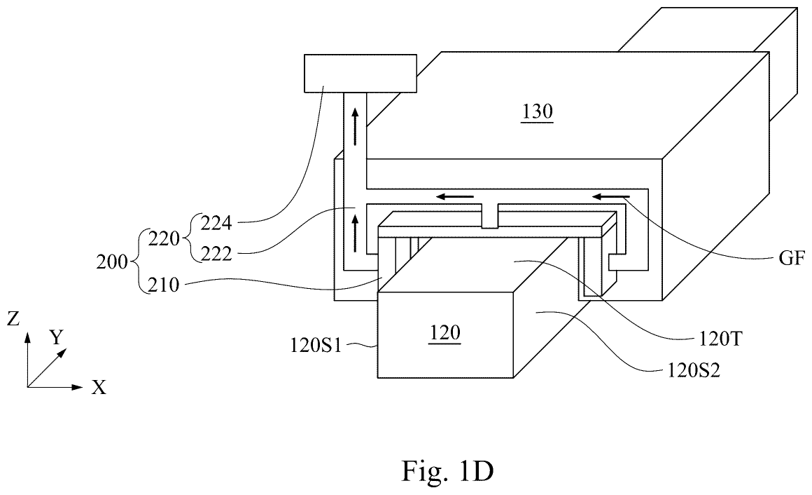

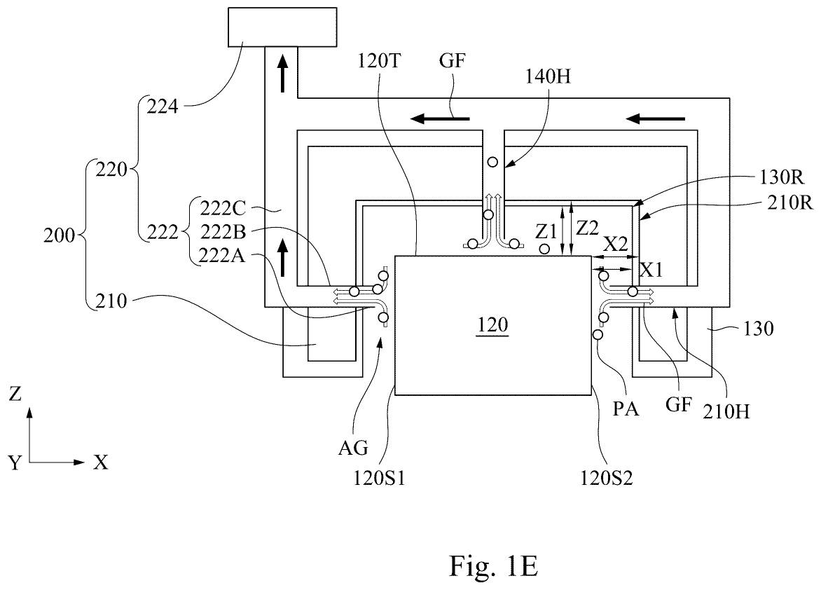

FIGS. 1A and 1B are schematic views of an inspection apparatus 100 according to some embodiments of the present disclosure. The inspection apparatus 100 includes a stage 110, rails 120, vehicles 130, a moving mechanism 140, and an inspection device 190. A reticle M is supported by the stage 110. In this context, the terms reticle, mask, and photomask are used interchangeably. In the present embodiments, the reticle M is a reflective mask. One exemplary structure of the reticle M includes a substrate with a low thermal expansion material (LTEM). For example, the LTEM may include TiO₂ doped SiO₂, or other suitable materials with low thermal expansion. The reticle M includes a reflective multi-layer deposited on the substrate. The reflective multi-layer includes plural film pairs, such as molybdenum-silicon (Mo/Si) film pairs (e.g., a layer of molybdenum above or below a layer of silicon in each film pair). Alternatively, the reflective multi-layer may include molybdenum-beryllium (Mo/Be) film pairs, or other suitable materials that are configurable to highly reflect the extreme ultraviolet (EUV) light. The reticle M may further include a capping layer, such as ruthenium (Ru), disposed on the reflective multi-layer for protection. The reticle M further includes an absorption layer, such as a tantalum boron nitride (TaBN) layer, deposited over the reflective multi-layer. The absorption layer is patterned to define a layer of an integrated circuit (IC). The reticle M may have other structures or configurations in various embodiments.

Each of the rails 120 may be a linear guide extending along a direction Y. The vehicles 130 may move (e.g., slide) on the rails 120 along the direction Y. The stage 110 may include a stage 110Y and a stage 110X over the stage 110Y. The stage 110Y is supported by the vehicles 130 and therefore can be moved along the direction Y. The moving mechanism 140 may control the stage 110X to move along a direction X. The reticle M supported by the stage 110X may have a surface with a surface normal direction in a direction Z, in which the directions X, Y, Z are orthogonal to each other. In the context, the vehicles 130 may be referred to as runners, sliders, slide members. The rails 120 and the vehicles 130 may be made of suitable rigid materials, such as ceramics (e.g., aluminum oxides). In some embodiments, the rails 120 and the vehicles 130 are components of the air slide AB, which is non-contact type bearing where the air pressure flows against the rail 120 through a restrictive nozzle of the vehicles 130 to uplift and control precision movement of the vehicles 130. For the non-contact type bearing, an air gap AG may be between the rail 120 and the vehicle 130. For example, a distance X1 (referring to FIG. 1D later) between the rail 120 and the vehicle 130 measured along the direction X may be in a range from about 1 micrometer to about 100 micrometers. And, a distance Z1 (referring to FIG. 1D later) between the rail 120 and the vehicle 130 measured along the direction Z may be in a range from about 1 micrometer to about 100 micrometers. In the illustrated embodiments, the stage 110Y is supported by two vehicles 130 and moves on two rails 120. In some alternative embodiments, the number of the vehicles 130 that supports the stage 110Y, and the numbers of the rails 120 that the stage 110Y moves on may vary according to various design requirements.

The inspection device 190 may include a light source and a light sensor, in which the light source provides an inspection light IL onto the reticle M, and the light sensor detects a light IL′ reflected by the reticle M. The inspection light IL may be a laser beam, in which the wavelength of the laser beam can be reflected by the patterns of the reticle M. In some embodiments, the wavelength of the laser beam can be different from that EUV light. The inspection device 190 is stationary, and can provide the light IL toward and detect light IL′ from a stationary inspection position IP. By moving the reticle M by the stages 110X and 110Y to locate the different portions of the reticle M at the inspection position IP in a time sequence, the reticle M can be inspected in a real-time manner. As a result, an inspection result of a map/image of the reticle M with defect information can be obtained.

FIG. 1C is a top view of the inspection apparatus 100 of FIGS. 1A and 1B. FIG. 1D is a schematic view of a portion of an inspection apparatus 100 of FIG. 1C. FIG. 1E is a side schematic view of FIG. 1D. FIG. 1F is a schematic view of a gas distributing structure and a cleaning mechanism of FIG. 1D. The inspection apparatus 100 may further include a cleaning mechanism 200, which includes gas distributing structures 210 and a gas suction system 220.

In some embodiments, the gas distributing structures 210 may be disposed at opposite sides of one of the vehicles 130 along the direction Y. The gas distributing structures 210 may be made of any suitable rigid material, such as stainless steel, ceramics, or any suitable materials. Each of the gas distributing structures 210 includes one or more holes 210H penetrating through itself.

In some embodiments, the gas suction system 220 comprises gas lines 222 and a gas suction source 224, in which the gas lines 222 fluidly connects the gas suction source 224 to the gas distributing structures 210. The gas lines 222 may be referred to as gas pipes in some embodiments. The gas suction source 224 may be capable of providing suctioning force, thereby inducing suctioning gas flows GF from the gas distributing structures 210, through the gas lines 222, to the gas suction source 224. For example, the gas suction source 224 may be a vacuum source. Through the holes 210H, the gas flows GF may flow from a first side of the gas distributing structure 210 adjacent the rail 120 to a second side of the gas distributing structure 210 opposite to the rail 120.

During the movement of the vehicle 130 over the rail 120, the vehicle 130 may touches (or scratches) the rail 120, which may create particles PA near the vehicle 130 and the rail 120. The particles PA may contaminate the reticle M, which may worsen the inspection result of the map/image of the reticle M.

In some embodiments of the present disclosure, by using the cleaning mechanism 200, the particles PA adjacent the rail 120 may be carried by the gas flows GF to leave the rail 120, thereby cleaning the rail 120. As a result, the particles PA may be effectively removed from the vehicle 130 and the rail 120, for example, removed from a chamber of the inspection apparatus 100 accommodating the rail 120, the vehicle 130, the moving mechanism 140, and the reticle M. Therefore, the reticle M can be kept from the particles, thereby improving the inspection result of the map/image of the reticle M. The vehicles 130 and the gas distributing structures 210 may respectively surround the rail 120. For example, the vehicles 130 and the gas distributing structures 210 may respectively have recesses 130R and 210R accommodating the rail 120. In some embodiments, referring to FIGS. 1A-1D, the inspection apparatus 100 may include a wall 100W surrounding the stages 110X and 110Y, the rails 120, the vehicles 130, the inspection device 190, and the gas distributing structures 210.

FIG. 1E is a schematic view of a vehicle 130 and a cleaning mechanism 200 of FIG. 1C. Reference is made to FIGS. 1C-1E. In the present embodiments, the gas line 222 may extend through the holes 210H. For example, the gas line 222 may have a first line portion 222A on the first side of the gas distributing structure 210 adjacent the rail 120, a second line portion 222B in the holes 210H, and a third line portion 222C on the second side of the gas distributing structure 210 opposite to the rail 120. In some other embodiments, the gas line 222 may not have the third line portion 222C on the second side of the gas distributing structure 210 opposite to the rail 120. In some other embodiments, the holes 210H are fluidly connected with the gas line 222, in which the gas line 222 may not have the second line portion 222B in the holes 210H and the third line portion 222C on the second side of the gas distributing structure 210 opposite to the rail 120.

The rail 120 may have a top side 120T, a first lateral side 120S1, and a second lateral side 120S2 extending along the direction Y, and the first lateral side 120S1 and the second lateral side 120S2 are opposite to each other. In the present embodiments, the holes 210H of the gas distributing structure 210 is over the top side 120T, the first lateral side 120S1, and the second lateral side 120S2 of the rail 120. As a result, the gas flows GF may flow away from the rail 120 along the direction Z, the direction X, and a direction opposite to the direction X. In some alternative embodiments, the holes 210H of the gas distributing structure 210 may be located at one or two of the top side 120T, the first lateral side 120S1, and the second lateral side 120S2 of the rail 120.

In the present embodiments, the rail 120 has a rectangular cross-sectional profile. And, the gas distributing structure 210 and the vehicle 130 may have a U-shape cross-sectional profile which coincides with the rail 120. The gas distributing structure 210 may be disposed away from the rail 120, thereby avoiding colliding the rail 120 during movement. In some embodiments, a distance X2 between the rail 120 and the gas distributing structure 210 measured along the direction X is equal to or greater than the distance X1. For example, the distance X2 is greater than the distance X1 and less than one hundred times the distance X1. And, in some embodiments, a distance Z2 between the rail 120 and the gas distributing structure 210 measured along the direction Z is equal to or greater than the distance Z1. For example, the distance Z2 is greater than the distance Z1 and less than one hundred times the distance Z1. If the distance Z2 is less the distance Z1, and/or the distance X2 is less than the distance X1, the gas distributing structure 210 may collide the rail 120 during movement. If the distance Z2 is greater than one hundred times the distance Z1, and/or the distance X2 is greater than one hundred times the distance X1, the vacuum force provided by gas suction system 220 may be lowered. In some embodiments, a top surface of the gas distributing structures 210 is lower than a top surface of the vehicles 130, and the gas distributing structures 210 may not extend beyond opposite sidewalls of the vehicles 130 along the direction X for maintaining vacuum force provided by gas suction system 220.

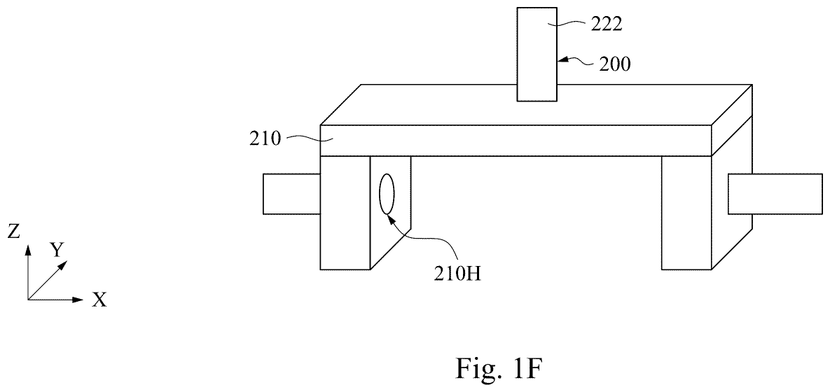

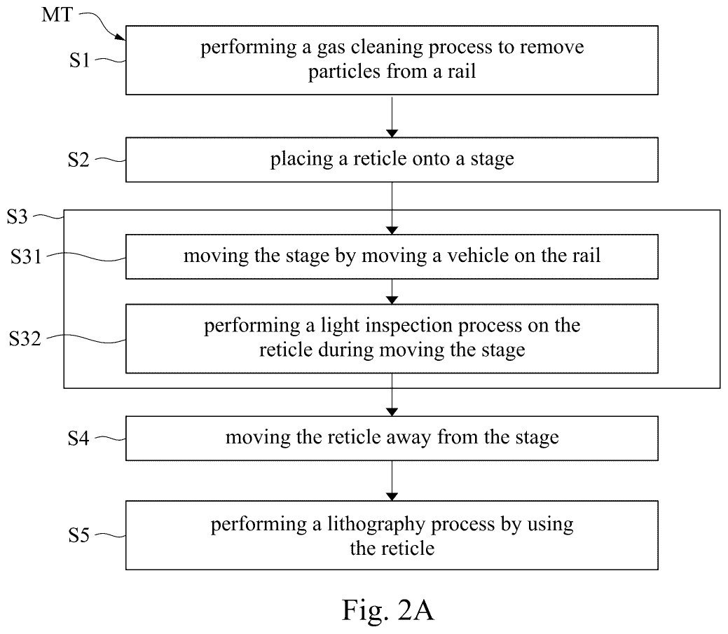

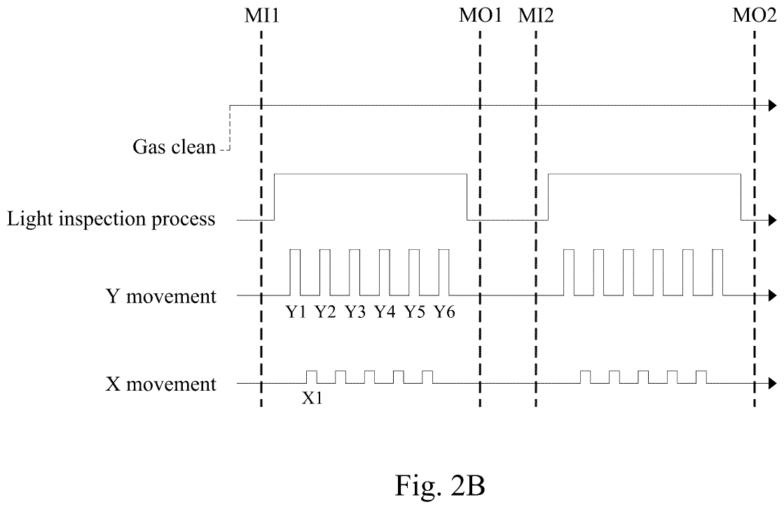

FIG. 2A is a flow chart of a method MT for operating an inspection apparatus 100 according to some embodiments of the present disclosure. The method MT includes steps S1-S5. It is understood that additional steps may be provided before, during, and after the steps S1-S5 shown in FIG. 2A, and some of the steps described below can be replaced or eliminated for additional embodiments of the method. The order of the operations/processes may be interchangeable.

Reference is made to FIGS. 2A, 1A, and 1D. The method begins at step S1, where a gas cleaning process is performed to remove particles PA from a rail 120. As aforementioned, the cleaning mechanism 200 may provide the suction gas flow GF to carry particles PA from the rail 120.

The method MT proceeds to step S2, where a reticle M is placed onto the stage 110X. In some embodiments of the present disclosure, the gas cleaning process at step S1 continues before, during, and after the reticle M is placed onto the stage 110X. That is, the gas cleaning process can be performed when the stage 110X is absent from a reticle and when the stage 110X supports the reticle M. In some embodiments, for improving precisions in the subsequent lithography process (e.g., step S5), the reticle M placed on the stage 110X may not be equipped with a pellicle thereon. For example, prior to the step S1, a pellicle is removed from the reticle M, and the reticle M is directly used in the subsequent lithography process (e.g., step S5) after the step S4. In some embodiments, the reticle M placed on the stage 110X may be equipped with a pellicle thereon to protect the reticle M from being contaminated by particles.

The method MT proceeds to at step S3, where an inspection process is performed to obtain a map/image of the reticle M including defect information. As aforementioned, in some embodiments, the inspection process at step S3 may be performed when the reticle M is not equipped with the pellicle. In some alternative embodiments, the inspection step may be performed when the reticle M is equipped with the pellicle.

The step S3 may include repeating steps S31 and S32. At step S31, the stage 110Y is moved by moving a vehicle 130 on the rail 120, such that the reticle M is moved.

At step S32, a light inspection process is performed the reticle M during moving the stage 110Y. For example, during the movement, the inspection light IL (in FIG. 1A) can be impinged onto the reticle M and a light IL′ (in FIG. 1A) reflected by the reticle M can be detected. Through the steps S31 and S32, the reticle M is scanned, and a map/image of the reticle M including defect information can be obtained. In some embodiments of the present disclosure, the gas cleaning process at step S1 continues before, during, and after the inspection process.

The method MT proceeds to at step S4, where the reticle M is moved away from the stage 110X. In some embodiments of the present disclosure, the gas cleaning process at step S1 continues before, during, and after the reticle M is moved away from the stage 110X.

The method MT proceeds to at step S5, where a lithography process is performed by using the reticle M. For example, the reticle M is placed in the lithography apparatus, which may be an extreme ultraviolet (EUV) lithography system designed to expose a resist layer by EUV light (or EUV radiation). The resist layer is a material sensitive to the EUV light. The EUV lithography system employs a radiation source to generate EUV light, such as EUV light having a wavelength ranging between about 1 nm and about 100 nm. The reticle M may reflect the EUV light from the radiation source to a semiconductor substrate coated with the resist layer. Through the configuration, imaging the pattern of the reticle M is imaged onto a semiconductor substrate.

FIG. 2B shows pulses versus time for operating an inspection apparatus according to some embodiments of the present disclosure. FIG. 2C shows a top view of the inspection apparatus under the operation of FIG. 2B. Reference is made to FIGS. 2A-2C. Four dashed bold lines MI1, MO1, MI2, MO2 are used to indicate the timing of reticle transfer. The dashed bold line MI1 indicates the timing when a first reticle M is placed onto the stage 110X. The dashed bold line MO1 indicates the timing when the first reticle M is removed from the stage 110X. The dashed bold line MI2 indicates the timing when a second reticle M is placed onto the stage 110X. The dashed bold line MO2 indicates the timing when the first reticle M is removed from the stage 110. In some embodiments, in regardless of the reticle M being placed on the stage 110 or not, the gas cleaning process is kept being performed. The inspection process is performed during the time interval between the dashed bold lines WI1 and WO1 (or the time interval between the dashed bold lines WI2 and WO2).

The inspection process at step S3 may include the movement of the stage 110 at step S31 and the inspection step at step S32. The movement of the stage 110 at step S31 may include the movement along the direction Y (“Y movement”) and the movement along the direction X (“X movement”), as the pulses shown in FIGS. 2B and 2C. The arrow lines (e.g., the arrow lines IP1-IP6) respectively indicate the path of the inspection position IP on the reticle M during the pulses Y1-Y6. For example, at the pulse Y1 in Y movement, regions of a first line of the reticle Mare respectively moved to the inspection position (e.g., the inspection position IP in FIG. 1A) and inspected in a time sequence. After the pulse Y1, the stage 110 is moved along the direction X to inspect next line, as the pulse X1 shown in the X movement. Subsequently, at the pulse Y2 in Y movement, regions of a second line of the reticle M are respectively moved to the inspection position (e.g., the inspection position IP in FIG. 1A) and inspected in a time sequence. For example, the line IP2 indicates the path of the inspection position IP (in FIG. 1A) on the reticle M during the pulse Y2.

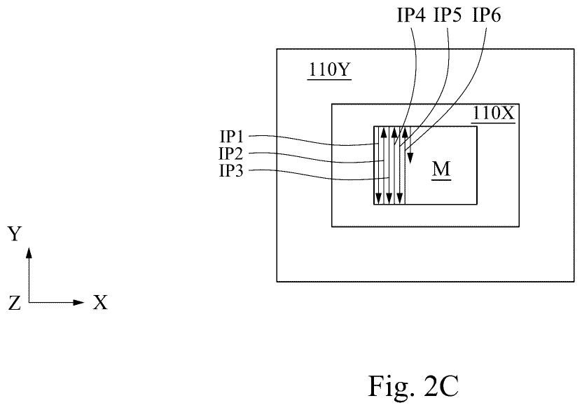

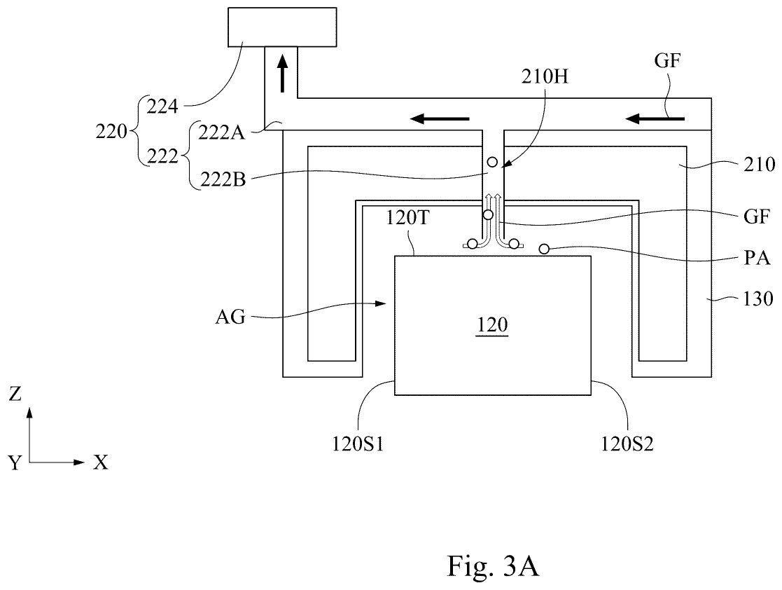

FIG. 3A is a side schematic view of a portion of an inspection apparatus according to some embodiments of the present disclosure. FIG. 3B is a schematic view of a gas distributing structure 210 and a cleaning mechanism 200 according to some embodiments of the present disclosure. Details of the present embodiments are similar to the embodiments of FIGS. 1A-2B, except that the holes 210H of the gas distributing structure 210 is over the top side 120T of the rail 120. The gas distributing structure 210 may have no holes adjacent to the first lateral side 120S1 and the second lateral side 120S2 of the rail 120. As a result, the gas flow GF mainly flows away from the rail 120 along the direction Z. Other details of the present embodiments are similar to the embodiments of FIGS. 1A-2B, and therefore not repeated herein.

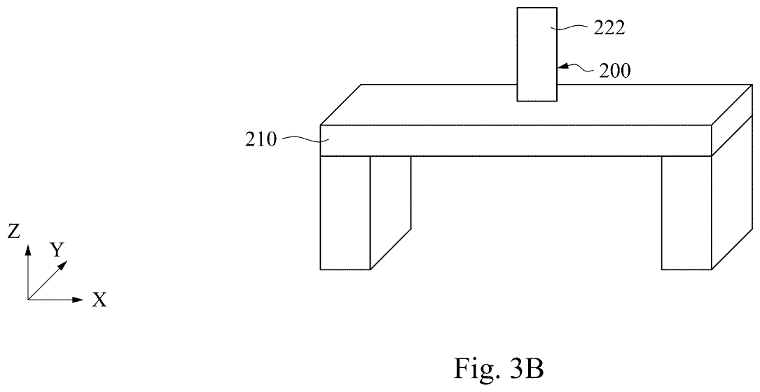

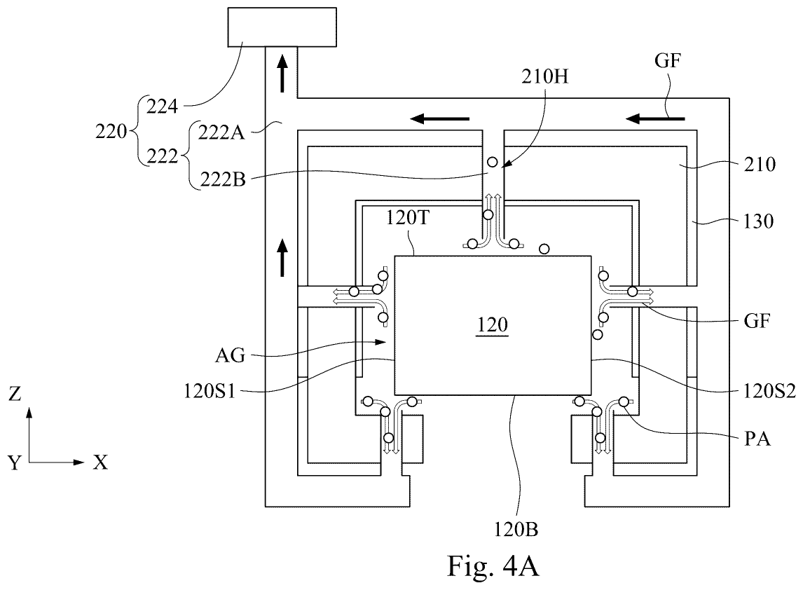

FIG. 4A is a side schematic view of a portion of an inspection apparatus according to some embodiments of the present disclosure. FIG. 4B is a schematic view of a gas distributing structure 210 and a cleaning mechanism 200 according to some embodiments of the present disclosure. Details of the present embodiments are similar to the embodiments of FIGS. 1A-2B, except that the holes 210H of the gas distributing structure 210 is over the top side 120T, the first lateral side 120S1, the second lateral side 120S2, and the bottom side 120B of the rail 120. As a result, the gas flows GF may flow away from the rail 120 along the direction Z, a direction opposite to the direction Z, the direction X, and a direction opposite to the direction X. Other details of the present embodiments are similar to the embodiments of FIGS. 1A-2B, and therefore not repeated herein.

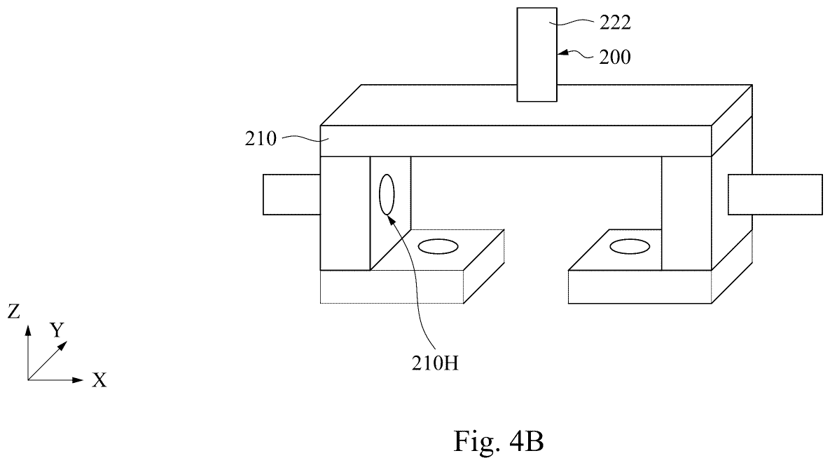

FIG. 5 is a schematic view of a gas distributing structure 210 and a cleaning mechanism 200 according to some embodiments of the present disclosure. Details of the present embodiments are similar to the embodiments of FIGS. 1A-2B, except that the cleaning mechanism 200 may further include a gas purge system 230. The gas purge system 230 comprises a gas line 232 and a gas purge source 234, in which the gas line 232 fluidly connects the gas purge source 234 to the gas distributing structure 210. The gas purge source 234 may be capable of providing purging gas flow PG to the rail 120 through the gas line 232 and the gas distributing structure 210. The purging gas flow PG may include clean dry air (CDA), such as nitrogen.

In some embodiments, the gas line 232 may extend through some of the holes 210H of the gas distributing structure 210. In some embodiments, the gas line 232 may be fluidly connected with the holes 210H of the gas distributing structure 210. Through the holes 210V, the purging gas flow PG may flow from a first side of the gas distributing structure 210 adjacent the rail 120 to a second side of the gas distributing structure 210 opposite to the rail 120. Through the configuration, particles PA adjacent the rail 120 may be blown away from the rail 120 by the purging gas flow PG, thereby cleaning the rail 120.

In the present embodiments, the gas purge system 230 may provide the purging gas flow PG through the holes 210H of the gas distributing structure 210 on the first lateral side 120S1 and the second lateral side 120S2 of the rail 120, and the gas suction system 220 may induce the gas flow GF through the holes 210H of the gas distributing structure 210 on the top side 120T of the gas suction system 220. In some alternative embodiments, the gas purge system 230 may provide the purging gas flow PG through any suitable hole 210H of the gas distributing structure 210, and the gas suction system 220 induce the gas flow GF through any suitable holes 210H of the gas distributing structure 210. Other details of the present embodiments are similar to the embodiments of FIGS. 1A-2B, and therefore not repeated herein.

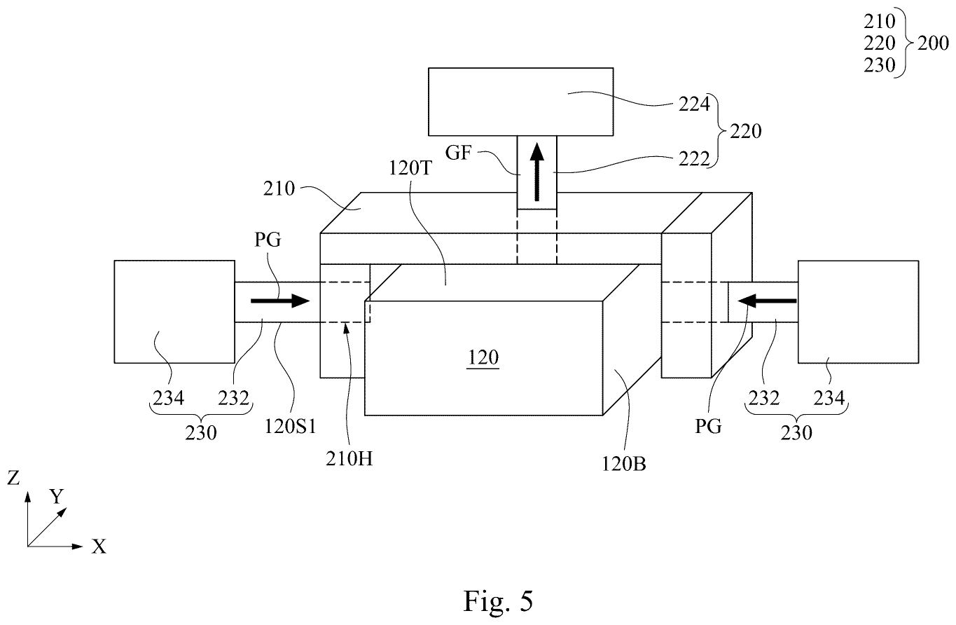

FIG. 6 is a schematic view of a gas distributing structure 210 and a cleaning mechanism 200 according to some embodiments of the present disclosure. Each of the holes 210H of the gas distributing structure 210 is fluidly connected with one of the gas lines of the cleaning mechanism 200 (the gas line 222 or 232 in FIG. 5). The holes 210H may have a circular cross-sectional profile. The gas line 222 and/or 232 may be fluidly connected with the holes 210H according to device requirement. Other details of the present embodiments are similar to those illustrated above, and therefore not repeated herein.

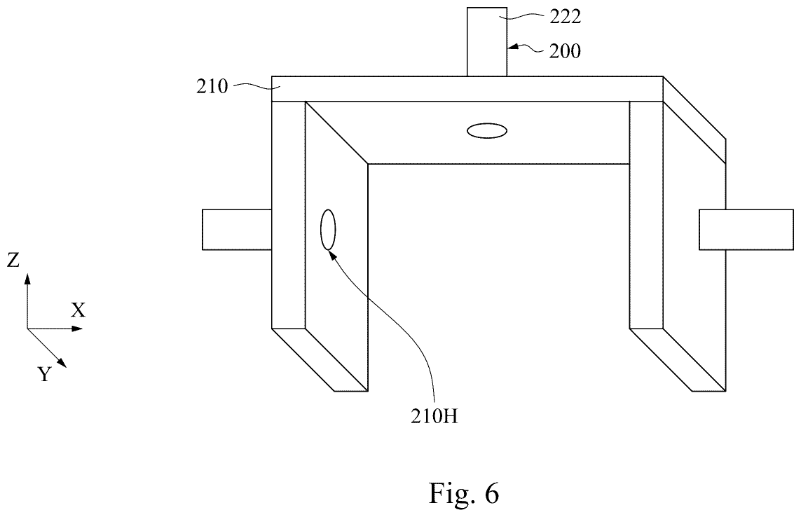

FIG. 7 is a schematic view of a gas distributing structure 210 and a cleaning mechanism 200 according to some embodiments of the present disclosure. Details of the present embodiments are similar to those illustrated in FIG. 6, except that the gas distributing structure 210 may have plural holes 210H fluidly connected with one of the gas lines of the cleaning mechanism 200 (the gas line 222 or 232 in FIG. 5). The gas line 222 and/or 232 may be fluidly connected with the holes 210H according to device requirement. Other details of the present embodiments are similar to the embodiments of FIG. 6, and therefore not repeated herein.

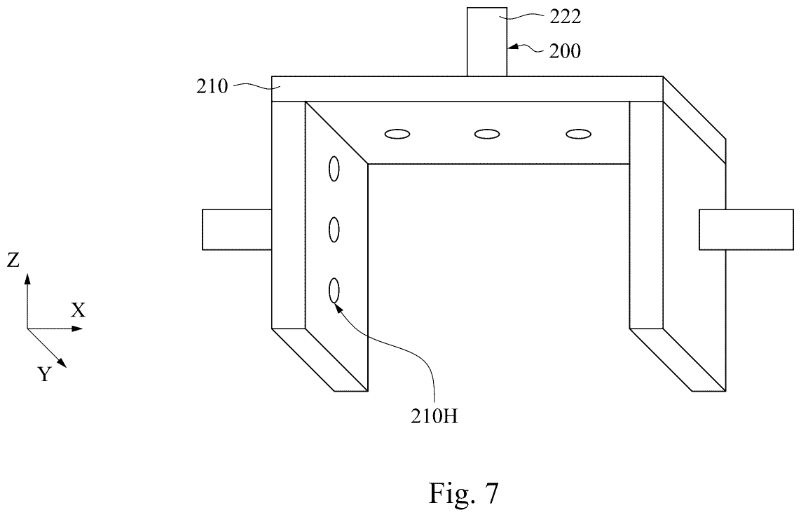

FIG. 8 is a schematic view of a gas distributing structure 210 and a cleaning mechanism 200 according to some embodiments of the present disclosure. Details of the present embodiments are similar to those illustrated in FIG. 6, except that the holes 210H may have a rectangular cross-sectional profile. In some embodiments, the holes 210H may have a square cross-sectional profile. The gas line 222 and/or 232 may be fluidly connected with the holes 210H according to device requirement. Other details of the present embodiments are similar to the embodiments of FIG. 6, and therefore not repeated herein.

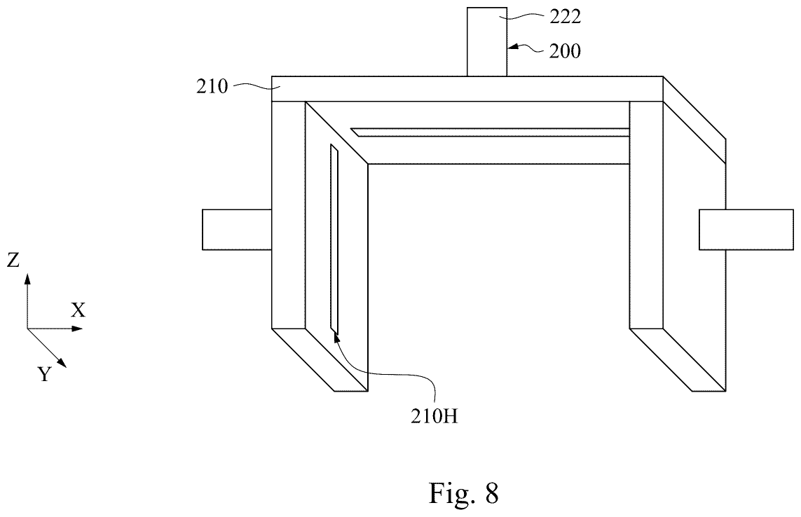

FIG. 9 is a schematic view of a gas distributing structure 210 and a cleaning mechanism 200 according to some embodiments of the present disclosure. Details of the present embodiments are similar to those illustrated in FIG. 6, except that the holes 210H may have a funnel cross-sectional profile. For example, a first width of the holes 210H adjacent to the rail 120 (referring to FIG. 1D) is greater than a second width of the holes 210H away from the rail 120 (referring to FIG. 1D). Other details of the present embodiments are similar to the embodiments of FIG. 6, and therefore not repeated herein.

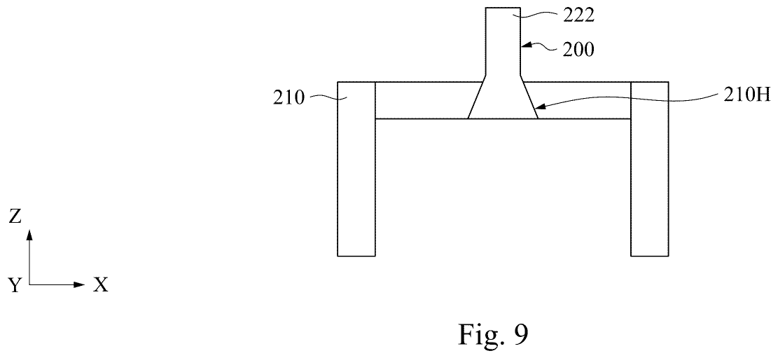

FIG. 10 is a side schematic view of a portion of an inspection apparatus according to some embodiments of the present disclosure. Details of the present embodiments are similar to those illustrated in FIG. 1D, except that the rail 120 has a circular cross-sectional profile. And, the gas distributing structure 210 and the vehicle 130 may have a round cross-sectional profile which coincides with the rail 120. For example, the gas distributing structure 210 and vehicle 130 may also have a circular cross-sectional profile. Other details of the present embodiments are similar to the embodiments of FIG. 1D, and therefore not repeated herein.

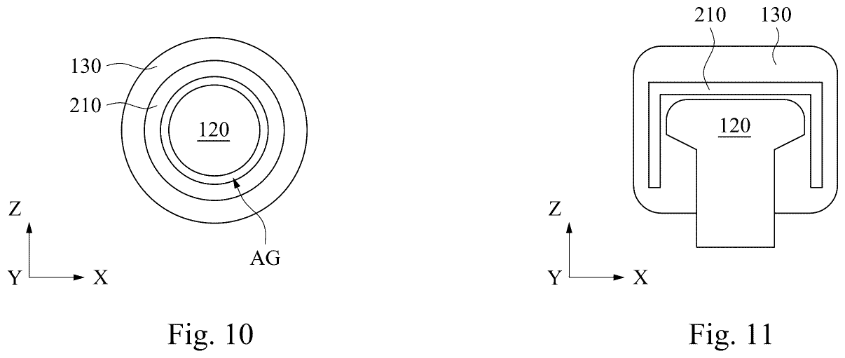

FIG. 11 is a side schematic view of a portion of an inspection apparatus according to some embodiments of the present disclosure. Details of the present embodiments are similar to those illustrated in FIG. 1D, except that the rail 120 has an irregular cross-sectional profile. And, the gas distributing structure 210 and vehicle 130 may have a shape which coincides with the rail 120. Other details of the present embodiments are similar to the embodiments of FIG. 1D, and therefore not repeated herein.

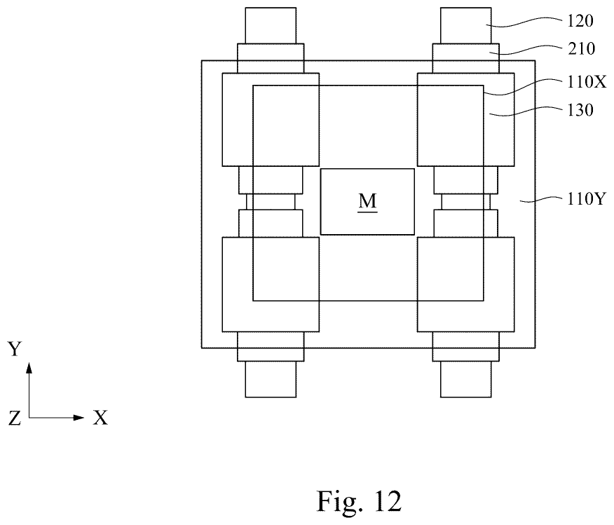

FIG. 12 is a top view of a portion of an inspection apparatus according to some embodiments of the present disclosure. Details of the present embodiments are similar to those illustrated in FIG. 1D, except that the stage 110Y may be supported by four vehicles 130 and moves on two rails 120. Similarly, the gas distributing structures 210 may be disposed at opposite sides of one of the vehicles 130 along the direction Y. Other details of the present embodiments are similar to the embodiments of FIG. 1B, and therefore not repeated herein.

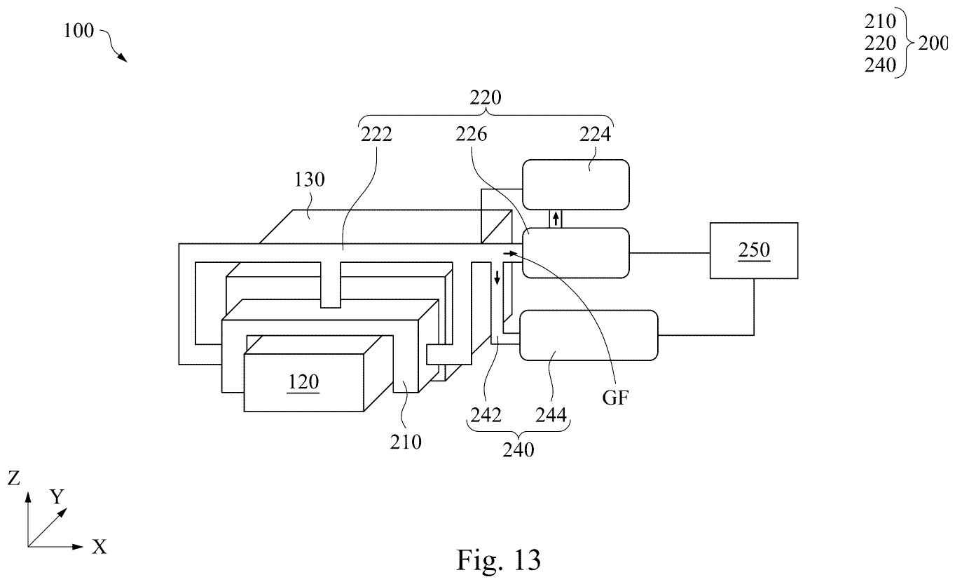

FIG. 13 is a schematic view of a portion of an inspection apparatus 100 according to some embodiments of the present disclosure. Details of the present embodiments are similar to those illustrated in FIG. 1D, except that the cleaning mechanism 200 may further include a particle sensor system 240. The particle sensor system 240 comprises a gas line 242 and a particle sensor 244, in which the gas line 242 has a first end fluidly coupled with the gas line 222 of the gas suction system 220 and a second end connected with the particle sensor 244. In some embodiments, the particle sensor 244 may detect and determine a behavior of particles (e.g., a number of particles, an average size of particles, and a concentration of particles) by optical reflection, image judgement, acoustic means, the like, or the combination thereof. With the particle sensor system 240, a behavior of particles in the gas flow GF can be obtained.

In some embodiments, a controller 250 may be electrically connected with the particle sensor 244 and the gas suction system 220. The controller 250 may dynamically adjust a vacuum force of the gas suction system 220 (e.g., an amount of suction gas flows GF) based on the behavior of particles (e.g., a number of particles, an average size of particles, and a concentration of particles) detected by the particle sensor 244. The gas suction system 220 may include an electronic pressure regulator 226, which may be a gas valve fluidly coupled with the gas lines 222 and the gas suction source 224. In some embodiments, the controller 250 receives signals/data from the particle sensor 244 and sends command to the electronic pressure regulator 226 of the gas suction system 220 fluidly coupled with the gas lines 222 based on the signals/data, thereby adjusting a vacuum force of the gas suction system 220 (e.g., an amount of suction gas flows GF) by adjusting a size of a valve opening of the electronic pressure regulator 226.

The controller 250 may be a part of an overall inspection apparatus 100 or a part of the cleaning mechanism 200. The controller 250 may include electronic memory and one or more electronic processors configured to execute programming instructions stored in the electronic memory, which may involve a program controlling the gas suction system 220 based on the signals/data from the particle sensor 244. In some embodiments, the controller 250 may include processors, central processing units (CPU), multi-processors, distributed processing systems, application specific integrated circuits (ASIC), or the like.

In some alternative embodiments, the cleaning mechanism 200 may further include any suitable sensors detecting physical parameters of the gas flow GF, and the gas suction system 220 may be activated or adjusted based on the detected physical parameters of the gas flow GF. For example, the sensors of the cleaning mechanism 200 may be image sensor, temperature sensor, the like, or the combination thereof.

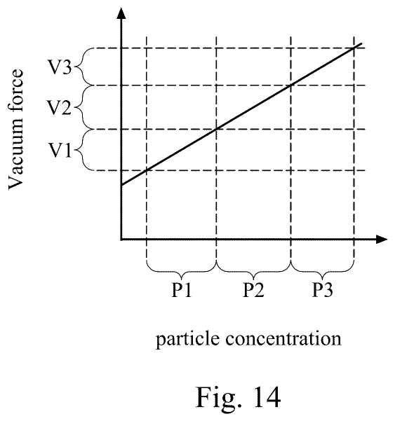

FIG. 14 is a diagram illustrating a relationship between a vacuum force of a gas suction system 220 and a particle concentration according to some embodiments of the present disclosure. Reference is made to both FIG. 13 and FIG. 14. By the controller 250, when the particle concentration detected by the particle sensor 244 is in a first concentration range P1, the gas suction system 220 may be controlled to provide a vacuum force is in a first vacuum range V1; when the particle concentration detected by the particle sensor 244 is in a second concentration range P2, the gas suction system 220 may be controlled to provide a vacuum force is in a second vacuum range V2; and when the particle concentration detected by the particle sensor 244 is in a third concentration range P3, the gas suction system 220 may be controlled to provide a vacuum force is in a third vacuum range V3. The first to third concentration ranges P1-P3 increase in a sequence, and the first to third vacuum ranges V1-V3 increase in a sequence. The relationship between the vacuum force of the gas suction system 220 and the particle concentration is exemplarily shown as a linear relationship in the present embodiments. In some other embodiments, the vacuum force of the gas suction system 220 and the particle concentration may be in a non-linear relationship.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that particles generated during the movement of the vehicles on the rail can be suppressed by a cleaning mechanism, thereby reducing the number of the particles on the reticle surface, which is beneficial to minimize the impact of mask repair lead-time on production. Another advantage is that the cleaning mechanism is adapted for various size of vehicles by changing the diameter of pipe for different size of vehicles.

According to some embodiments of the present disclosure, a method for operating an inspection apparatus is provided. The method includes placing a reticle over a stage; moving the stage by moving a vehicle supporting the stage on a rail; inspecting the reticle over the stage; and using a cleaning mechanism, generating a suction force nearby the rail.

According to some embodiments of the present disclosure, a method for operating an inspection apparatus is provided. The method includes placing a reticle over a stage; moving the stage by moving a vehicle supporting the stage on a rail; inspecting the reticle over the stage; and using a cleaning mechanism, providing a purging gas flow nearby the rail.

According to some embodiments of the present disclosure, an inspection apparatus includes a stage, a rail, a vehicle configured to support the stage and move on a rail, and a cleaning mechanism. The cleaning mechanism includes a gas distribution structure at a side the vehicle and a gas suction source fluidly connected with the gas distribution structure. The gas suction source is configured to generate a suction force nearby the rail through a first hole of the gas distribution structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for operating an inspection apparatus, comprising:
placing a reticle over a stage;
moving the stage by moving a vehicle supporting the stage on a rail;
inspecting the reticle over the stage; and
using a cleaning mechanism, generating a suction force nearby the rail.

2. The method of claim 1, wherein the suction force removes a particle away from the rail.

3. The method of claim 1, wherein the suction force is generated during moving the vehicle on the rail.

4. The method of claim 1, wherein the suction force is generated during inspecting the reticle.

5. The method of claim 1, wherein moving the stage is performed such that the reticle is moved back and forth at an inspection position.

6. The method of claim 1, wherein the cleaning mechanism comprises a gas distribution structure at a side the vehicle and a gas suction source fluidly connected with the gas distribution structure, and the suction force is generating through a hole of the gas distribution structure.

7. The method of claim 1, wherein the suction force is generated at a top side of the rail.

8. The method of claim 1, wherein the suction force is generated at a lateral side of the rail.

9. A method for operating an inspection apparatus, comprising:
placing a reticle over a stage;
moving the stage by moving a vehicle supporting the stage on a rail;
inspecting the reticle over the stage; and
using a cleaning mechanism, providing a purging gas flow nearby the rail.

10. The method of claim 9, wherein the purging gas flow is providing during moving the vehicle on the rail.

11. The method of claim 9, wherein the purging gas flow is generated during inspecting the reticle.

12. The method of claim 1, wherein the cleaning mechanism comprises a gas distribution structure at a side the vehicle and a purging source fluidly connected with the gas distribution structure, and the purging gas flow is provided through a hole of the gas distribution structure.

13. The method of claim 1, wherein the purging gas flow is provided at a top side of the rail.

14. The method of claim 1, wherein the purging gas flow is provided at a lateral side of the rail.

15. An inspection apparatus, comprising:
a stage;
a rail;
a vehicle configured to support the stage and move on the rail; and
a cleaning mechanism, comprising:
a gas distribution structure at a side the vehicle; and
a gas suction source fluidly connected with the gas distribution structure, wherein the gas suction source is configured to generate a suction force nearby the rail through a first hole of the gas distribution structure.

16. The inspection apparatus of claim 15, wherein the cleaning mechanism further comprises:
a purging source fluidly connected with the gas distribution structure, wherein the purging source is configured to provide a purging gas flow nearby the rail through a second hole of the gas distribution structure.

17. The inspection apparatus of claim 15, wherein a distance between the rail and the gas distribution structure is greater than a distance between the rail and the vehicle.

18. The inspection apparatus of claim 15, wherein the gas distribution structure surrounds the rail.

19. The inspection apparatus of claim 15, wherein the gas distribution structure has a recess accommodating the rail.

20. The inspection apparatus of claim 15, wherein the cleaning mechanism further comprises a gas line fluidly connecting the gas suction source to the gas distribution structure, and the gas line extends through the first hole of the gas distribution structure.
